(19) United States
(12) Patent Application Publication
(10) Pub. No.: US 2008/0311725 A1
(43) Pub. Date: Dec. 18, 2008

(54) Method For Assembling Substrates By Depositing An Oxide Or Nitride Thin Bonding Layer

(76) Inventors: Lea Di Cioccio, Saint Ismier (JP); Marek Kostrzewa, Grenoble (FR); Marc Zussy, Saint Egreve (FR)

Correspondence Address: BRINKS HOFER GILSON & LIONE, P.O. BOX 10395, CHICAGO, IL, 60610, US

(21) Appl. No.: 11/994,636

(22) PCT Filed: Jul. 5, 2006
(86) PCT No.: PCT/FR2006/001596

§ 371 Date: Feb. 4, 2008

(30) Foreign Application Priority Data
Jul. 6, 2005 (FR) 0507206

(51) Int. Cl. H01L 21/30

(52) U.S. Cl. 438/455; 257/E21.211

(57) ABSTRACT

A method for assembling by molecular bonding two substrates, at least one of which is made of a semiconductor material characterised in that one of substrates, called a first substrate, includes a surface (A), where at least one portion is flat and provided with an initial surface roughness compatible with the molecular bonding. The inventive method consists in depositing a thin oxide or nitride bonding layer, whose thickness ranges from 10 to 20 nm, on at least one portion of the surface flat part of the first substrate for carrying out a molecular bonding without pre-polishing, in saturating the thin bonding layer with hydroxyl groups, in bringing the thin bonding layer saturated with hydroxyl groups in contact with the second substrate (10) surface (B) which is at least locally flat with respect to the flat part of the surface (A) and saturated with hydroxyl groups and in carrying out a hydrophilic molecular bonding between said two substrates.

### PRIORITY CLAIM

This application is a U.S. nationalization of PCT Application No. PCT/FR2006/001596, filed Jul. 5, 2006, and claims priority to French Patent Application No. 0507206, filed Jul. 6, 2005.

### TECHNICAL FIELD

The invention relates to a method of assembling by molecular bonding two substrates at least one of which is made from a semiconductor material.

### BACKGROUND

There is currently a trend for greater complexity in the development of integrated circuits.

In fact at present integrated circuits are no longer simple electronic circuits but integrate other circuits with diverse functionalities: circuits with optical functions, high-frequency circuits, and even molecular and bio-electronic circuits. In the electronics field, silicon is the material most widely used, but if other functions such as those listed above are used, it is found that other materials offer significantly better performance than silicon for implementing those additional functions. It would therefore appear necessary to be able to integrate other materials onto silicon to satisfy the increasing development of integrated circuits that are no longer simple electronic circuits.

The integration of one or more materials on silicon, or even on some other semiconductor material, depends on the circuit that is to be fabricated and therefore on the target application, which necessitates adapting the integration technology to each integrated circuit.

Thus for certain applications it is indispensable to have a bonding interface that has good thermal conductivity in order to ensure sufficient power dissipation, with a low light absorption coefficient to satisfy requirements linked to opto-electronic applications, having a high temperature and vacuum resistance, and so on.

To this end, it appears necessary to select adhesive materials having appropriate properties.

Moreover, it should also be noted that it is possible, after integrating one or more materials onto silicon using judiciously chosen adhesives, to use other techniques such as heat treatment, deposition of oxides, epitaxial growth, etc.

Now, the use of adhesive materials such as epoxy resins, acrylic resins, and the like, to assemble together circuits produced in different materials, or even to produce “flip-chip” type assemblies, is difficult to make compatible with the techniques described above (heat treatment, deposition of oxides, epitaxial growth, and the like), in particular because of the high temperatures that are used.

However, these techniques are commonly used to assemble integrated circuits into their packaging or to fabricate certain hybrid circuits.

The paper entitled “Low-Temperature Direct CVD Oxides to Thermal Oxide Wafer Bonding in Silicon Layer Transfer” by C. S. Tan, K. N. Chen, A. Fan and R. Reif, Electrochemicals and Solid-State Letters, 8 (1) G1-G4, 2004 describes the assembly by molecular bonding of silicon substrates and SOI (Silicon On Insulator) type substrates.

A 5 000 Å thermal oxide coating is formed on the two different type substrates.

On the SOI type substrates coated in this way, a 1 μm thickness of oxide is deposited by chemical vapor deposition (CVD).

The surfaces coated in this way with oxide have a high roughness which is unfavorable to subsequent molecular adhesion.

The authors of the above paper therefore propose chemical mechanical polishing (CMP) of the surfaces of the SOI substrates coated with an oxide layer. The latter surfaces are then cleaned and saturated with hydroxyl groups by wet chemical treatment, just like the thermal oxide coated surfaces of silicon substrates, and the two different type substrates prepared in this way are then joined together in pairs.

However, this technique is not suited to the assembly of thin substrates, for example substrates of the order of 200 μm thick or less, which are liable to be weakened, or even to break, during the polishing step and therefore do not stand up well to thinning.

Moreover, the chemical mechanical polishing step is difficult to use on surfaces having a relief or on structured surfaces.

It is equally difficult to use locally on a surface portion.

Moreover, for certain materials, wet chemical treatment of the surfaces of the substrates to be bonded is not possible.

For example, the material InP is not directly compatible with SC (Standard Cleaning) treatment using a solution of ammonia and oxygenated water as conventionally used for saturation with hydroxyl groups.

It would consequently be useful to have an assembly technique that could be applied even when wet chemical treatment of the surfaces to be assembled is impossible.

### SUMMARY

Given the foregoing, the Applicant therefore proposes integrating one or more materials onto a semiconductor material such as silicon by molecular bonding, thereby avoiding the use of any adhesive material. This bonding by molecular adhesion produces very good mechanical strength, good thermal conductivity, and most importantly a uniform thickness of the bonding interface.

The present invention aims to eliminate at least one of the drawbacks cited above by proposing a method of assembling by molecular bonding two substrates at least one of which is produced in a semiconductor material, characterized in that one of the substrates, called the first substrate, has a surface A at least part of which is plane and has an initial surface roughness compatible with molecular bonding, the method including the following steps:

depositing onto at least a portion of the plane portion of the surface A of the first substrate, a thin bonding layer of oxide or nitride between 10 and 20 nm thick to enable molecular bonding with no preliminary polishing step,

saturating the thin bonding layer with hydroxyl groups,

bringing the thin bonding layer saturated with hydroxyl groups into contact with a surface B of the second substrate that is at least locally plane facing the portion of the plane portion of the surface A and is saturated with hydroxyl groups,

hydrophilic type molecular bonding between the two substrates.

According to the invention, there is deposited onto a surface of a substrate with an initial roughness suited to molecular bonding a thin bonding layer of controlled thickness sufficiently small not to modify the initial surface roughness. The surface roughness of the deposited thin layer remains sufficiently low and compatible with the molecular adhesion process for no polishing step to be necessary after depositing this thin layer.

This simplifies and therefore shortens the preparation of the surfaces before bonding.

Moreover, thin, and therefore fragile, substrates can be assembled by the method of the invention without risk of a polishing step damaging them, because it is entirely possible to deposit a thin layer on a thinned substrate.

Note that depositing a thin layer of oxide or nitride on a substrate makes the surface of the substrate hydrophilic, which enables subsequent molecular bonding of hydrophilic type.

Generally speaking, the invention is also of benefit when it is required to assemble by molecular bonding two substrates one of which has a weak buried interface, which would be incompatible with a chemical mechanical polishing step.

That interface can in particular be that with the bonding oxide or nitride.

According to one feature, the initial (rms) surface roughness of the surface A is less than 0.5 nm.

This kind of value is entirely compatible with molecular bonding.

Note that if the surface roughness after depositing the thin layer remains less than or equal to 0.5 nm, the bonding energy operative between the two substrates after molecular adhesion is substantially constant and of high value.

However, it may be beneficial to assemble two substrates with a controlled but lower bonding energy. It is therefore possible, for example, to increase slightly the initial surface roughness, whilst remaining within acceptable limits so that molecular bonding can be effected with no prior polishing step after depositing the thin layer.

According to one feature, the oxide is chosen from the following oxides: SiO₂, Al₂O₃, metal oxides.

The nitride is chosen from the following compounds: Si₃N₄, AlN, AlNO₃.

The oxide or nitride deposit makes the surface A of the first substrate hydrophilic.

Note that the surface B of the second substrate intended to be bonded to the surface A prepared in this way can be prepared like the surface A (deposition of a thin layer of oxide or nitride and saturation with hydroxyl groups), or in another way, provided that such other way integrates a step of saturation of the surface B with hydroxyl groups.

According to one feature, the saturation with hydroxyl groups is effected by chemical treatment, for example in a standard cleaning (SC) solution of oxygenated water and ammonia.

According to one feature, the saturation with hydroxyl groups is effected by non-chemical treatment, for example by means of ultraviolet radiation and in the presence of ozone.

By way of example, plasma treatment could be used as another non-chemical treatment.

For a substrate prepared beforehand, in particular to have a roughness compatible with molecular bonding, treatment of the substrate only with UV radiation in the presence of ozone does not enable molecular bonding with another substrate. This is the case in particular if the substrate undergoes a storage or transportation step after the preparation step.

Rather than repeating the preparation, the deposition of a bonding layer in accordance with the invention, associated with UV/ozone treatment, enables such bonding.

The preparation step (in terms of roughness) can therefore be dissociated from the bonding step and in particular substrates of appropriate roughness could be supplied and assembled subsequently in accordance with the invention.

After assembly, the structure obtained is subjected to a heat treatment that increases the bonding energy between the two substrates.

According to one feature, the semiconductor material is chosen from the following materials: silicon, InP, germanium and gallium arsenide, GaN, SiC, SiGe. It can be a bulk material or obtained by epitaxial growth.

Moreover, the other substrate can be produced in an amorphous material such as glass, like BPSG.

The invention finds one particularly beneficial application when one of the materials to be assembled is an amorphous material such as glass with creep capacities.

In fact, the roughness of a glass layer is generally too high to enable molecular bonding to be effected without a preliminary polishing step.

Now, polishing glass is a difficult operation and therefore somewhat undesirable in this instance.

However, as soon as a layer of glass has been obtained by deposition on a substrate, for example a silicon substrate, it is possible to effect a creep heat treatment operation after depositing the glass layer.

This heat treatment has a two-fold role, on the one hand, it densities and chemically stabilizes the glass and, on the other hand, it flattens the upper surface of the glass layer by creep.

Thus, once the plane surface has been obtained, the deposition of a thin layer of oxide or nitride followed by treatment to render it hydrophilic can be carried out with a view to molecular bonding of this glass layer with a substrate produced in a semiconductor material in accordance with the invention.

Another aspect of the invention concerns a method for assembling by molecular bonding a plurality of substrates with a support substrate, characterized in that each of the substrates, called the first substrate, that is to be assembled with the support substrate, called the second substrate, is assembled by the assembly method briefly described hereinabove.

According to one feature, each first substrate is an integrated circuit transferred onto the support substrate.

The assembly method according to the invention produces a structure including at least two substrates having between them at least one deposited thin layer of oxide or nitride and assembled by molecular bonding.

This kind of structure can be obtained more easily and more quickly than in the prior art since no polishing step is necessary to produce the molecular bonding.

Moreover, the substrates constituting this structure can be particularly thin, for example 200 μm thick.

Moreover, the substrates that are assembled by molecular bonding in accordance with the invention can also be of a kind not well suited to wet chemical treatment of their surface.

It should be noted that the assembly method of the invention can produce a structure including more than two substrates (for example, integrated circuits) produced in different materials and assembled by molecular bonding to a common support substrate through the intermediary of one or more identical or different thin layers of oxide or nitride deposited on the surfaces to be bonded.

According to one feature, the second substrate is a substrate forming a support for a plurality of substrates each assembled by molecular bonding of one of their surfaces which is at least locally plane and has an initial surface roughness compatible with molecular bonding to an at least locally plane surface of the support substrate, the molecular bonding being obtained by a thin bonding layer of oxide or nitride sufficiently thin to be compatible with molecular bonding and deposited on one or more of the at least locally plane surfaces that are brought into contact.

According to one feature, the first substrate and the other substrate(s) are assembled to the support substrate via surfaces with smaller dimensions than the total surface of the support substrate.

According to another feature, the substrates assembled to the support substrate therefore form a plurality of mesas projecting relative to the surface of the support substrate.

In a method carried out in accordance with the invention, it is therefore possible, by molecular bonding, to integrate microchips (integrated circuits) with diverse functions produced in different materials on the same support substrate using at least one deposited thin bonding layer of oxide or nitride.

It should be noted that the method of the invention can be applied to the production of heterostructures, i.e. enables assembly of substrates and/or thin layers of different materials, and in particular materials having very different coefficients of thermal expansion.

By way of example there may be cited assemblies such as InP on Si or GaAs on Si, and more generally assemblies involving III, V materials.

The entire process can be carried out at low temperature, which is entirely suitable for structures whose materials have very different coefficients of thermal expansion: the oxide deposit can be produced (including densification) at between 120 and 380°, bonding at room temperature and bonding reinforcement heat treatment between 200 and 450°.

### BRIEF DESCRIPTION OF THE DRAWING

FIGS. 1 to 9 illustrate, in cross-section, the successive steps of assembling one example of a composite structure assembled in accordance with the invention.

### DETAIL DESCRIPTION

As represented in FIG. 1, the surface of a support substrate 10, for example of silicon, was coated with a layer of thermal oxide (thermal SiO₂).

Alternatively, the support substrate is produced in CMOS processed silicon, for example, i.e. silicon having undergone technology steps for producing all or part of electronic components. Generally speaking, CMOS substrates are covered with a final thick deposited oxide passivating layer.

This thick oxide layer was then polished by chemical mechanical polishing in order to obtain a level of roughness compatible with molecular bonding, and then saturated with hydroxyl groups to encourage subsequent molecular bonding of the substrate 10 coated with this prepared layer 12.

Note that the layer 12 formed on the surface of the support substrate 10 could, if the substrate has satisfactory roughness, also be produced in the form of a thin oxide layer, and therefore necessitating no polishing step, which would subsequently be saturated with hydroxyl groups.

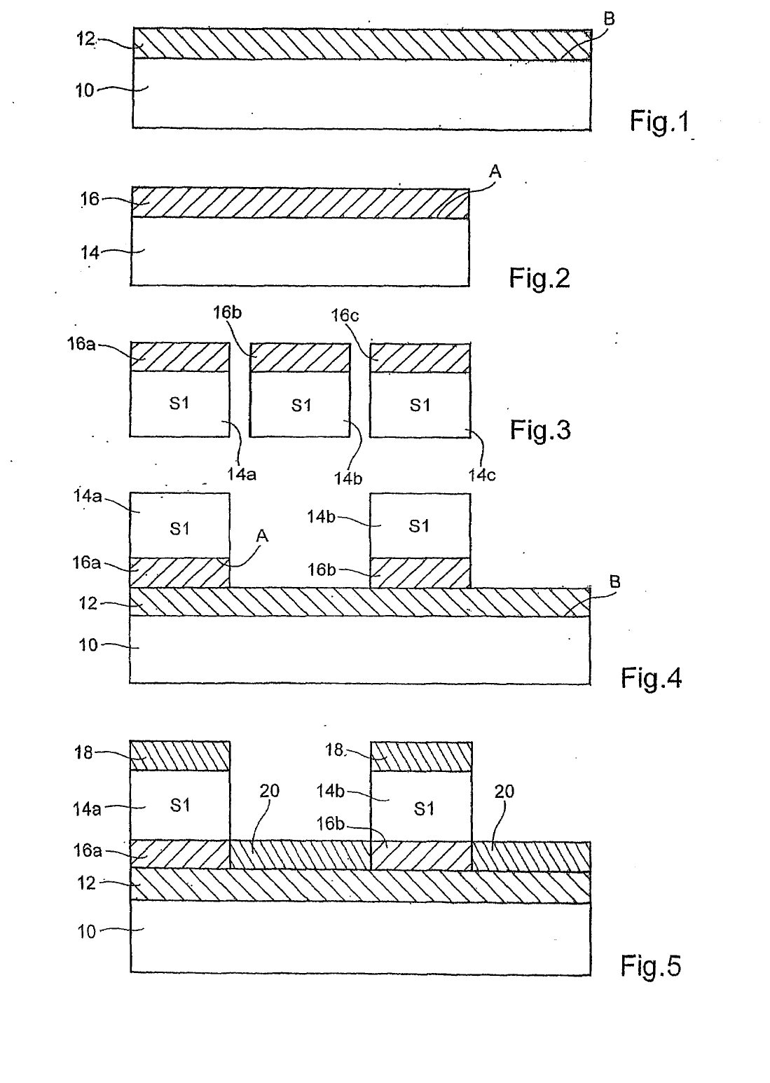

In FIG. 2 there is represented a substrate 14 produced in a semiconductor material chosen, for example, from silicon, InP, germanium, gallium arsenide, SiGe, SiC, GaN, garnet, etc.

The material chosen is InP, for example.

The surface A of the substrate 14 is coated with a thin bonding layer 16 of silicon nitride (Si₃N₄) with a thickness equal to 15 nm, for example, obtained by a PECVD type deposition technique.

The substrate 14 coated with the thin layer 16 is then cut up to form a plurality of substrates S1 referenced 14a, 14b, 14c each with smaller dimensions than the support substrate 10.

Each substrate 14a, 14b, 14c is coated with a thin bonding layer 16a, 16b, 16c and the latter are each saturated with hydroxyl groups to render the surfaces hydrophilic with a view to subsequent molecular bonding.

The thin layers with which the substrates 14a and 14b are coated are then brought into contact with the layer 12 of the support substrate 10, as represented in FIG. 4, in order for hydrophilic type molecular bonding to occur between the layers brought into contact, thus enabling assembly by molecular bonding of the different substrates by way of hydrogen bonds.

Note that in the composite structure assembled in this way represented in FIG. 4 the substrates 14a and 14b provided with their respective thin layers 16a and 16b form a plurality of mesas (transferred integrated circuits) that project from the surface of the support substrate 10.

It should also be noted that a bonding strengthening heat treatment can be carried out once the substrates (microchips or integrated circuits) have been bonded.

Technology steps can then be carried out before transferring other elements (microchips, etc.).

To be able to bond other substrates (microchips or integrated circuits) produced in the same material or in one or more other different materials to the support structure of the assembled structure represented in FIG. 4, the as yet unoccupied surface of the support substrate 10 must again be rendered hydrophilic.

To this end, as represented in FIG. 5, there is carried out a deposition of a thin layer of oxide, for example of SiO₂, with a thickness equal to 20 nm, for example, on the upper surfaces of the structure obtained in FIG. 4.

There is obtained in this way on the upper surface of the mesas a thin oxide layer 18 and on the upper surface of the layer 12 of the support substrate 10 a thin oxide layer 20.

Alternatively, the oxide can be deposited locally in the areas in which bonding is to be effected.

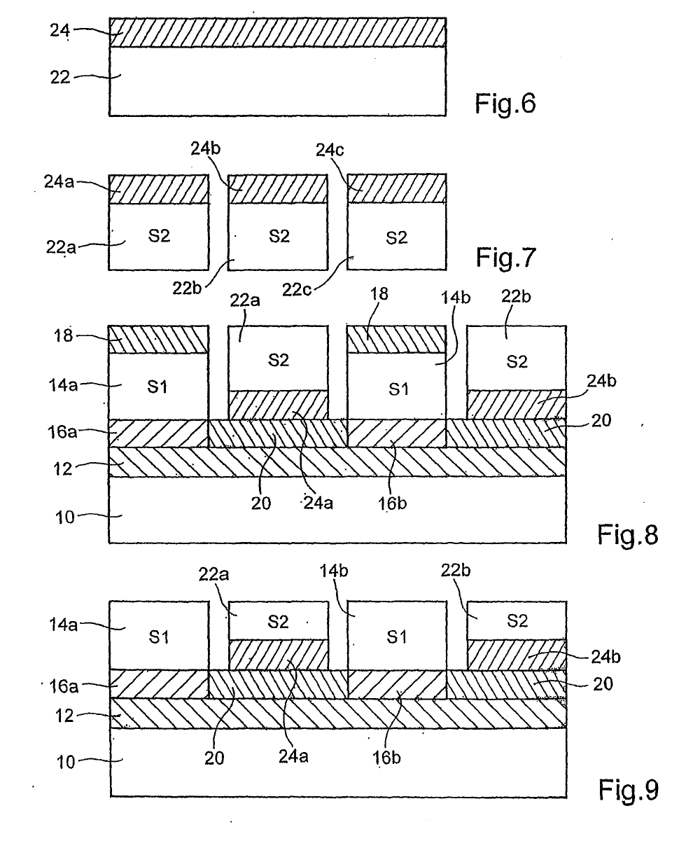

Moreover, as represented in FIG. 6, another substrate 22 is produced, for example in a semiconductor material such as GaAs, or for example in an amorphous material, and is coated with a thin layer 24, for example of silicon oxide.

The thin oxide layer 24 is deposited by a PECVD type deposition technique, for example, and has a thickness equal to 15 nm, for example.

As explained with reference to FIG. 3, the substrate 22 coated in this way is cut into a plurality of substrates S2 referenced 22a, 22b, 22c, each coated with a thin layer of oxide 24a, 24b, 24c, respectively (FIG. 7).

These layers are then saturated with hydroxyl groups in order to encourage subsequent hydrophilic type molecular bonding.

The respective thin layers saturated with hydroxyl groups of the substrates obtained in this way are then brought into contact with the thin layer 20 of the support substrate from FIG. 5 in order for molecular bonding of the surfaces brought into contact in this way to occur at room temperature (FIG. 8).

Note again that the substrates newly bonded to the support substrate form a plurality of mesas that project relative to the surface of the support substrate.

It should also be noted that a bonding strengthening heat treatment operation can also be carried out if necessary.

As illustrated in FIG. 9, finishing operations are carried out in order to eliminate the thin oxide layer 18 deposited on the upper surface of the mesas formed by the substrates S1 and etching operations can also be carried out.

The composite structure from FIG. 9 assembled in this way includes a plurality of substrates forming mesas that project relative to the surface of the support and which are interleaved with each other, for example.

The process can be repeated in this way to attach other elements (electronic microchips or integrated circuits).

Note further that the various substrates molecularly bonded by means of a thin oxide or nitride layer to the surface of the support substrate can be placed selectively in appropriate areas of the support substrate without necessarily being interleaved with each other.

In the embodiment represented in the FIG.s, the substrates S1 and S2 are produced in different materials that are also different from that of the support substrate.

However, structures including one or more substrates produced in the same material and forming mesas projecting relative to the support substrate can also be envisaged.

In the FIG.s, the support substrate has been represented in plane form but note that it can feature a relief, holes, micromechanical structures, etc.

Generally speaking, the thin oxide or nitride layer deposit according to the invention can be produced over all the surface of a plane substrate or only over preferred plane areas thereof, depending on the intended applications.

It should be noted that it is preferable not to stack the thin layers on the substrates, even if the thickness and the roughness of the latter are perfectly controlled, in order not to risk developing a surface roughness that could prejudice subsequent molecular bonding.

In FIGS. 3 and 7 there are represented substrates (microchips or integrated circuits) separated from a single substrate (respectively the substrate from FIGS. 2 and 6) and that includes a thin layer before separation. However, the thin layer can alternatively be deposited on the plurality of substrates resulting from the separation operation (known as “dicing”).

In fact, it has been observed that the redeposition of particles during the cutting operation does not impede subsequent bonding in that those particles can be eliminated by rinsing in water.

### EXAMPLE 1

For this experiment, eight silicon substrates or flat plates numbered 1 to 8 with standard dimensions (100 mm diameter and 525 μm thick) were prepared.

An oxide layer was grown on the upper face of each of the eight plates to a thickness of 400 nm.

The eight plates oxidized in this way were then cleaned in a solution of water and sulfuric acid, and then rinsed with water.

The oxidized and washed surfaces of the eight plates were polished by chemical mechanical polishing (CMP) to confer on the surfaces a low roughness of less than 0.5 nm (microroughness measured by atomic force microscopy (AFM)).

Note that during polishing approximately 150 nm of oxide were removed. PECVD type deposition of a thin oxide bonding layer SiO₂ 14 nm thick was effected on plates 3 and 4.

The plates 1 to 4 were then cleaned and activated chemically in the following manner:

cleaning the plates 1 to 4 in water, followed by exposure to ultraviolet radiation in the presence of ozone in order to saturate the oxidized surfaces of the plates with hydroxyl groups;

the plates treated in this way are then immersed in a bath containing a standard cleaning (SC) type solution of ammonia and oxygenated water to improve the saturation in hydroxyl groups;

the plates are thereafter rinsed in the water, and then dried.

The surfaces of the plates 1 to 4 prepared in this way were then brought into contact in respective pairs with the oxidized surfaces of the plates 5 to 8 in order to produce molecular bonding at room temperature.

Thus the plate 1 was bonded to the plate 5, the plate 2 to the plate 6, the plate 3 to the plate 7, and the plate 4 to the plate 8.

Furthermore, a bonding reinforcing heat treatment operation was carried out at a temperature of about 200° C.

The four plate structures 1/5, 2/6, 3/7 and 4/8 bonded in this way were exposed to infrared radiation to verify the quality of the molecular bonding and this infrared imaging test did not reveal any visible bonding defect.

To quantify the molecular bonding, the bonding energy of the four structures 1/5, 2/6, 3/7 and 4/8 was effected by the Maszara blade method.

The measurements revealed the same value of 610 mJ/m² for the four bonded structures.

These results confirm that surface preparation carried out under ultraviolet radiation in the presence of ozone is efficient and that the deposition of a thin (14 nm thick) oxide layer does not develop a surface roughness that would rule out subsequent molecular bonding.

### EXAMPLE 2

In this example eight plane plates of silicon numbered 1 to 8 with a diameter of 525 μm and a thickness of 100 mm were prepared.

A thin layer of oxide SiO₂ 19 nm thick was deposited by the PECVD type technique on the plates numbered 1 to 4.

These plates were then cleaned and chemically activated as indicated hereinafter:

cleaning in water and exposure to ultraviolet light in the presence of ozone to saturate the upper surfaces of these plates with hydroxyl groups;

drying of the plates 1 and 2;

the plates 3 and 4 were cleaned in an SC solution of ammonia and oxygenated water, and then rinsed in water and dried.

Moreover, a PECVD type deposit of silicon oxide 400 nm thick was produced on the upper surface of the silicon support plates numbered 5 to 8.

Those plates were then cleaned in a solution of sulfuric acid and oxygenated water (CARO type solution), polished in a CMP type polishing step to remove about 100 nm of oxide, and then rinsed in water and dried.

The prepared surfaces of the plates 1 and 2 were then brought into contact with the prepared surfaces of the support plates 5 and 6, respectively, for molecular bonding to occur at room temperature, thus producing the assembled structures of bonded plates 1/5 and 2/6.

The prepared surfaces of the plates 3 and 4 were likewise brought into contact with the preferred surfaces of the support plates 7 and 8, respectively, for molecular bonding of the surfaces brought into contact to occur at room temperature, thus leading to the assembled structures of bonded plates 3/7 and 4/8.

A bonded strengthening heat treatment operation was also effected at a temperature of about 200° C., thus producing an interface of good mechanical strength.

The bonding energy of the various structures obtained in this way was measured in exactly the same way as described for example 1 above and the following values were obtained in this way:

625 mJ/m² for the structures 1/5 and 2/6, 687 mJ/m² for the structure 3/7, 756 mJ/m² for the structure 4/8.

Given these results, it is found that the bonding energy is slightly higher if standard cleaning (SC) type cleaning is applied in addition to the UV/ozone treatment to clean the surfaces and saturate them with hydroxyl groups.

### EXAMPLE 3

A thin layer of SiO₂ oxide 19 nm thick was deposited by the PECVD type deposition technique on two plane silicon plates or substrates.

These plates were then chemically cleaned and activated in the following manner:

cleaning in water (rinsing), followed by exposure to ultraviolet radiation in the presence of ozone;

immersion of the plates cleaned in this way in an SC mixture of ammonia and oxygenated water;

rinsing in water and drying.

One of the treated surfaces of each plate chemically cleaned and activated in this way were then brought into contact in order to produce molecular bonding at room temperature.

The plates bonded in this way then underwent a heat treatment operation at a temperature of 200° C. to strengthen the molecular bond.

The bonding energy of the structure obtained in this way was measured under exactly the same conditions as before and revealed a value of 850 mJ/m², corresponding to bonding of very good quality.

1. A method of assembling first and second substrates by molecular bonding where at least one of the substrates comprises a semiconductor material, wherein the first substrate has a surface at least a portion of which is plannar and has an initial surface roughness compatible with molecular bonding, the method comprising:
depositing a thin bonding layer of oxide or nitride onto at least a portion of the plannar portion of the surface of the first substrate to a thickness of between 10 and 20 nm, such that the first substrate can be molecular bonded in the absence of a preliminary polishing step;
saturating the thin bonding layer with hydroxyl groups;
bringing the thin bonding layer saturated with hydroxyl groups into contact with a surface of the second substrate that is at least locally plannar and is saturated with hydroxyl groups; and
hydrophillically molecular bonding the first and second substrates.

2. The method according to claim 1, wherein the surface of the first substrate has root mean square (rms) initial surface roughness less than 0.5 nm.

3. The method according to claim 1, wherein depositing a thin bonding layer comprises depositing an oxide comprising SiO₂, Al₂O₃, or a metal oxide.

4. The method according to claim 1, wherein depositing a thin bonding layer comprises depositing a nitride comprising Si₃N₄, AlN, or AlNO₃.

5. The method according claim 1, wherein saturating the thin bonding layer with hydroxyl groups comprises carrying out a chemical treatment.

6. The method according to claim 1, wherein saturating the thin bonding layer with hydroxyl groups comprises irradiating the thin bonding layer with ultraviolet radiation in the presence of ozone.

7. The method according to claim 1, wherein saturating the thin bonding layer with hydroxyl groups comprises performing plasma treatment.

8. The method according to claim 1, further comprising dipping the thin bonding layer in a solution of ammonia after saturating the thin bonding layer with hydroxyl groups.

9. The method according to claim 1, wherein the semiconductor material comprises silicon, InP, Ge, gallium arsenide, GaN, SiC, or SiGe.

10. The method according to claim 1, wherein the other substrate comprises an amorphous material.

11. A method for assembling by molecular bonding a plurality of first substrates with a support substrate, wherein each of the plurality of substrates is assembled with the support substrate according to the method of claim 1.

12. The method according to claim 11, wherein each of the first substrates includes an integrated circuit transferred to the support substrate.
